(19) United States
(12) Patent Application Publication
(10) Pub. No.: US 2025/0199898 A1
(43) Pub. Date: Jun. 19, 2025

(54) INFORMATION PROCESSING APPARATUS, SEMICONDUCTOR CHIP, AND CONTROL METHOD

(71) Applicant: Premo Inc., Tokyo (JP)

(72) Inventors: Hidenori Tsuji, Tokyo (JP); Junta Miyamoto, Tokyo (JP); Shutai Okamura, Tokyo (JP)

(73) Assignee: Premo Inc., Tokyo (JP)

(21) Appl. No.: 19/071,076

(22) Filed: Mar. 5, 2025

Related U.S. Application Data
(63) Continuation of application No. PCT/JP2023/030808, filed on Aug. 25, 2023.

(30) Foreign Application Priority Data
Sep. 8, 2022 (JP) 2022-142979

(51) Int. Cl. G06F 11/07; H01L 25/16; H10B 80/00

(52) U.S. Cl. CPC G06F 11/0772; G06F 11/0721; H01L 25/16; H10B 80/00

(57) ABSTRACT

There is provided an information processing apparatus comprising a first semiconductor chip and a second semiconductor chip that performs wireless communication with the first semiconductor chip. The first semiconductor chip includes a processor that executes information processing, and a communication circuit configured to receive a wireless signal from the second semiconductor chip. The processor functions as a state determination unit configured to determine a state of at least one of the first semiconductor chip and the second semiconductor chip on a basis of a time-series change in a measurement value of the wireless signal received from the second semiconductor chip via the communication circuit.

### CROSS-REFERENCE TO RELATED APPLICATION(S)

This application is a continuation of International Patent Application No. PCT/JP2023/030808 filed on Aug. 25, 2023, which claims priority to and the benefit of Japanese Patent Application No. 2022-142979 filed on Sep. 8, 2022, the entire disclosures of which are incorporated herein by reference.

### BACKGROUND OF THE INVENTION

### Field of the Invention

The present invention relates to an information processing apparatus, a semiconductor chip, and a control method.

### Description of the Related Art

There is a conventionally known technique in which a plurality of semiconductor chips perform wireless communication with one another using coils; for example, Japanese Patent Laid-Open No. 2021-87044 proposes an information processing apparatus in which a plurality of semiconductor chips integrated in the horizontal direction exchange information with one another via short-distance wireless communication.

Here, in a case where an information processing apparatus using a plurality of semiconductor chips is used for a long period of time, there is a need to monitor normal operations of each semiconductor chip, and to, for example, fix or replace the same as necessary. However, with the conventional technique described in Japanese Patent Laid-Open No. 2021-87044, although it is possible to detect an interruption in communication with a neighboring semiconductor chip, it is difficult to ascertain the state of semiconductor chips, such as a failure in semiconductor chips and a change in a distance relationship among chips.

### SUMMARY OF THE INVENTION

The present invention has been made in view of the above-described background, and provides an information processing apparatus, a semiconductor chip, and a state monitoring apparatus capable of ascertaining the state of semiconductor chips.

According to an aspect of the present invention, there is provided an information processing apparatus comprising a first semiconductor chip and a second semiconductor chip that performs wireless communication with the first semiconductor chip, wherein the first semiconductor chip includes: a processor that executes information processing; and a communication circuit configured to receive a wireless signal from the second semiconductor chip, and the processor functions as a state determination unit configured to determine a state of at least one of the first semiconductor chip and the second semiconductor chip on a basis of a time-series change in a measurement value of the wireless signal received from the second semiconductor chip via the communication circuit.

Other problems and solutions therefor disclosed in the present application will become apparent from the description of embodiments of the invention and the drawings.

### BRIEF DESCRIPTION OF THE DRAWINGS

FIG. 1 is a diagram showing an exemplary overall configuration of an information processing apparatus according to an embodiment of the present invention;

FIG. 2 is a diagram showing an exemplary hardware configuration of the information processing apparatus corresponding to an embodiment of the present invention;

FIG. 3 is a block diagram showing a functional configuration of a semiconductor chip according to an embodiment of the present invention;

FIG. 4 is a control flow diagram showing the operations of the information processing apparatus according to an embodiment of the present invention;

FIG. 5 is a diagram showing an example of information stored in a measurement value storage unit of the present invention;

FIG. 6 is a diagram showing another example of information stored in the measurement value storage unit of the present invention;

FIG. 7 is a diagram showing examples of a wireless signal communicated between semiconductor chips according to an embodiment of the present invention, and a voltage value of a coil;

FIG. 8 is a diagram showing a first application example of the information processing apparatus of the present invention;

FIG. 9 is a diagram showing a second application example of the information processing apparatus of the present invention;

FIG. 10 is a diagram showing an example of a format of a wireless signal frame for sensing processing;

FIG. 11 is a flowchart of processing for obtaining an evaluation value of a wireless signal that a semiconductor chip 1 has received from another semiconductor chip 1 (evaluation value obtainment processing included in the sensing processing);

FIG. 12 is a flowchart of state determination processing included in the sensing processing;

FIG. 13 is a diagram showing an example of a format of a wireless signal frame for the sensing processing;

FIG. 14 is a diagram showing an example of a format of a wireless signal frame for the sensing processing;

FIG. 15 is a diagram showing an example of a format of an information frame; and

FIG. 16 is a flowchart of sensing processing that a semiconductor chip 1 executes based on a wireless signal transmitted to another semiconductor chip 1.

### DESCRIPTION OF THE EMBODIMENTS

### Overview of System

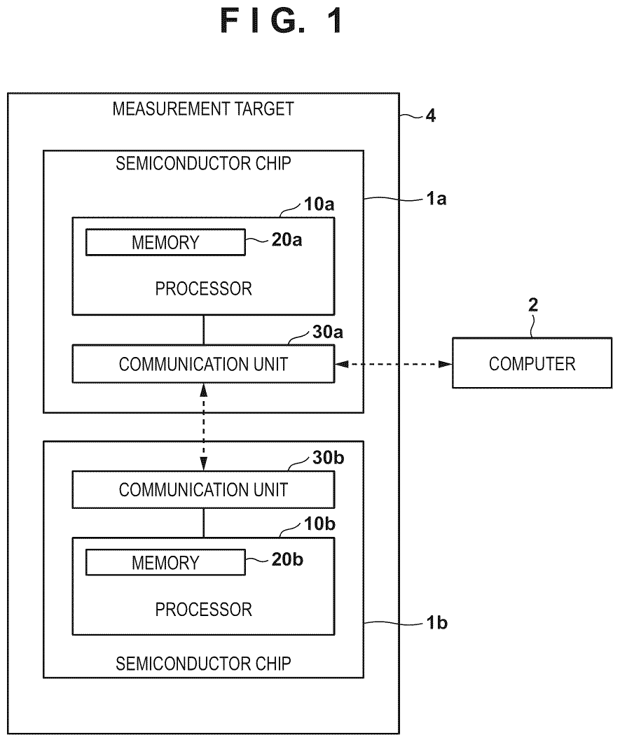

FIG. 1 is a diagram showing an exemplary configuration of an information processing apparatus according to an embodiment of the present invention. The information processing apparatus of the present embodiment is configured to include a plurality of semiconductor chips (1a, 1b). The semiconductor chips 1 are apparatuses capable of measuring, for example, a relative positional relationship with another semiconductor chip 1. The plurality of semiconductor chips 1 are located on a surface of or inside a measurement target 4, and are capable of measuring the state of the measurement target 4 (e.g., the operational state, deformation, temperature, vibration, pressure, electromagnetic waves, volume, humidity, and the like of the measurement target) by measuring a relative positional relationship with another semiconductor chip 1. For example, the measurement target 4 may be an apparatus on which an object like a door or a motor moves or deforms, may be a civil engineering or construction material like an embankment or concrete, or may be water, air, and the like.

The semiconductor chips 1 include a processor 10 and a communication unit 30, and the processor 10 includes a memory 20. At least a part of the memory 20 can include a nonvolatile storage device and store a program executed by the processor 10. The communication unit 30 can function as an antenna. The communication unit 30 can exchange signals with the communication unit 30 of another adjacently-located semiconductor chip 1 via inductive coupling (synonymous with near-field inductive coupling, electromagnetic coupling, and electromagnetic induction) or another communication method.

At least one of the plurality of semiconductor chips 1 (in FIG. 1, the semiconductor chip 1a ) is connected to a computer 2 in a communication-enabled manner. Communication between the computer 2 and the semiconductor chip 1 can be wireless communication performed via the communication unit 30. Note that the computer 2 and the semiconductor chip 1 can also perform wired communication with each other.

The computer 2 is a computer capable of, for example, analyzing a failure state of the semiconductor chips 1 and a relative positional relationship between the semiconductor chips by receiving at least one of the following detected by the semiconductor chip 1a itself: information indicating whether a failure has occurred in the semiconductor chip 1a itself or another semiconductor chip 1b with which wireless communication is performed, and information indicating a relative positional relationship between the semiconductor chip 1a itself and another semiconductor chip 1b.

The information processing apparatus of the present embodiment can calculate a relative positional relationship between the plurality of semiconductor chips 1 composing the information processing apparatus, and whether a failure has occurred therein. In a case where a relative positional relationship between the plurality of semiconductor chips 1 has been calculated and an absolute (e.g., indicated by a latitude and a longitude or the like) position of at least one of the plurality of semiconductor chips 1 has been given, the absolute positions of all of the plurality of semiconductor chips 1 can also be calculated.

### Hardware

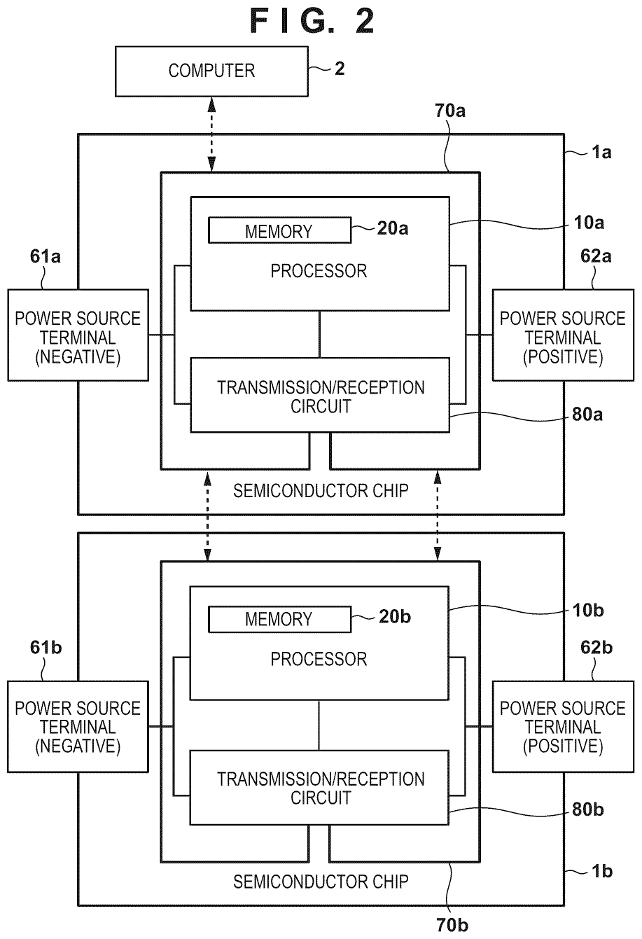

FIG. 2 shows an exemplary hardware configuration with an application of coils 70, which are provided around the outer peripheries of the processors inside the semiconductor chips 1, and transmission/reception circuits 80, as one example of realization of the communication units 30 (communication circuits). The example shown in FIG. 2 represents an example in which the semiconductor chips 1 are used in a pair, and the semiconductor chips 1 include a processor (10a, 10b), a memory (20a, 20b) provided inside the processor, a transmission/reception circuit (80a, 80b) which is connected to the processor in a communication-enabled manner and which generates signals that flow through a coil 70, a coil (70a, 70b) connected to the transmission/reception circuit, and a first power source terminal on the negative-electrode side (61a, 61b) and a second power source terminal on the positive-electrode side (62a, 62b) for supplying power to the processor and the transmission/reception circuit.

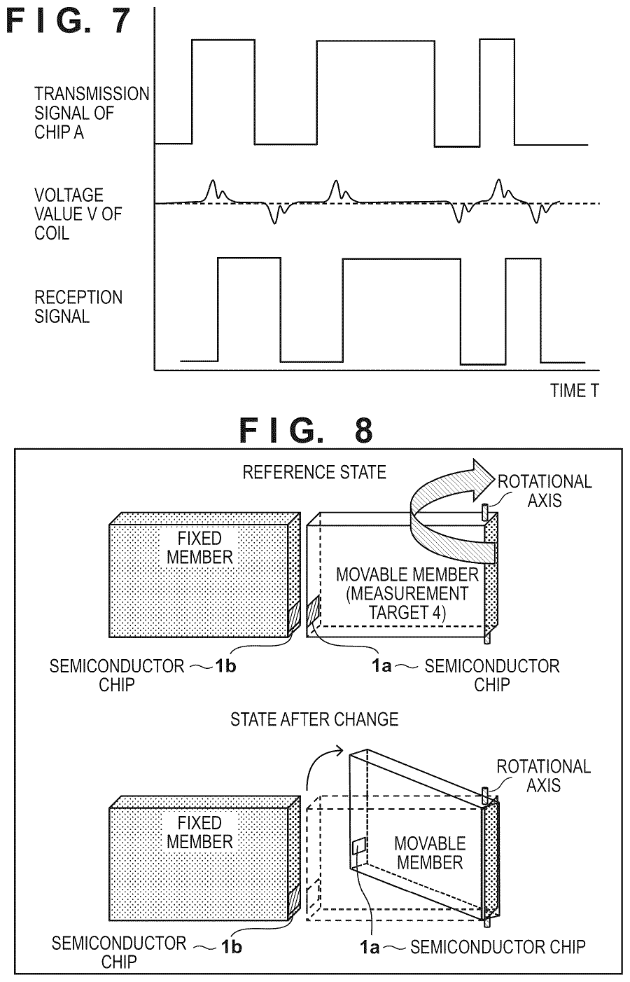

The first and second power source terminals can receive a power supply from outside the semiconductor chip. Note that the semiconductor chip may be configured to receive a wireless power supply, instead of receiving a power supply via the first and second power supply terminals as shown in FIG. 2. The coil 70 can function as an antenna. The coil 70 can exchange signals with the coil 70 of another adjacently-located semiconductor chip 1 via inductive coupling or another communication method. Furthermore, the coil 70 can similarly exchange signals also with the computer 2 via inductive coupling or another communication method. Here, FIG. 7 shows a voltage value obtained at the coil 70 from a transmission signal from a nearby semiconductor chip, and a reception signal generated based on this voltage value. In this way, the coil obtains a voltage value induced in the coil when receiving a wireless signal from a nearby semiconductor chip.

In the two adjacently-located semiconductor chips (1a, 1b) shown in FIG. 2, when the relative position between the coils (70a, 70b), which include at least one of a relative distance and a relative angle, has changed, the coupling intensity of inductive coupling changes, and the voltage values or voltage amplitudes that occur in the coils 70 change. In the present embodiment, as a result of detection of the voltage values or voltage amplitudes that occur in the coil 70 by the transmission/reception circuit 80, the processor 10 can obtain the detected voltage values or voltage amplitudes as measurement values, and detect a change in the relative position between the semiconductor chips, which include at least one of the relative distance and the relative angle. The memory 20 records the detected change in the relative position. Here, as shown in FIG. 7, the coil obtains, for example, the voltage values or voltage amplitudes induced in the coil as measurement values when receiving a wireless signal, and can determine that the relative positions of the chips therebetween have gotten away from each other in a case where the voltage amplitudes decreased, and determine that the relative positions of the chips therebetween have gotten close to each other in a case where the voltage amplitudes increased.

The semiconductor chip of the present embodiment can be configured with a CPU by inseparably mounting the processor and the communication unit shown in FIG. 2 on the semiconductor chip. In this case, the semiconductor chips can have a diameter of approximately 0.3 mm, for example, and the size of the semiconductor chips can be reduced. Note that this size is an example, and the size of the semiconductor chips of the present invention is not limited to this. For example, the processor and the communication unit can be inseparably mounted on a semiconductor chip (on a single chip). Here, the semiconductor chip is defined as a small, thin piece of silicon (a silicon die or a die) in which electronic circuits are embedded. Alternatively, depending on circumstances, the semiconductor chip can also be defined as a package in which a silicon die has been sealed.

### Software

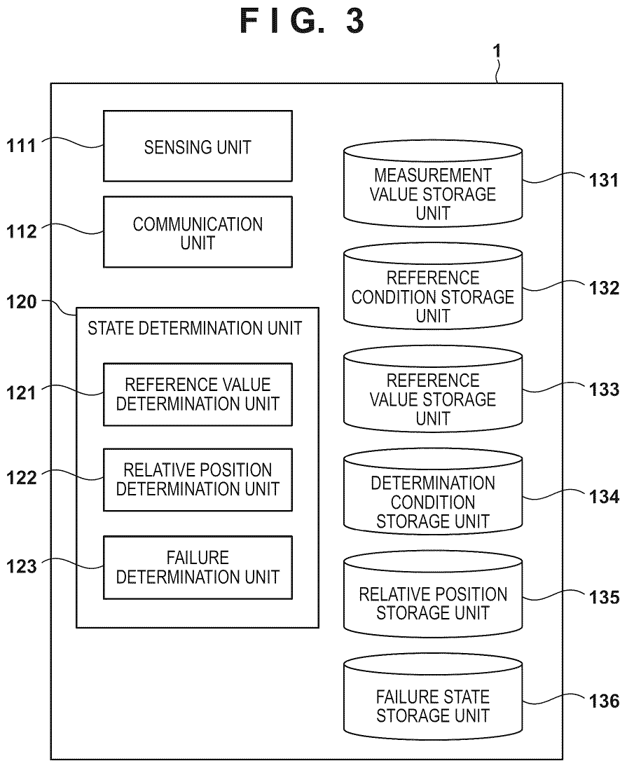

FIG. 3 is a block diagram showing a functional configuration of a semiconductor chip 1. The semiconductor chip 1 includes a sensing unit 111, a communication unit 112, a state determination unit 120, a measurement value storage unit 131, a reference condition storage unit 132, a reference value storage unit 133, a determination condition storage unit 134, a relative position storage unit 135, and a failure state storage unit 136, and the state determination unit 120 includes a reference value determination unit 121, a relative position determination unit 122, and a failure determination unit 123. The sensing unit 111, the communication unit 112, and the state determination unit 120 (the reference value determination unit 121, the relative position determination unit 122, and the failure determination unit 123) can be realized by the processor 10 included in the semiconductor chip executing a program stored in the memory 20. The measurement value storage unit 131, the reference condition storage unit 132, the reference value storage unit 133, the determination condition storage unit 134, the relative position storage unit 135, and the failure state storage unit 136 can be realized as a part of a storage area of the memory 20 included in the semiconductor chip.

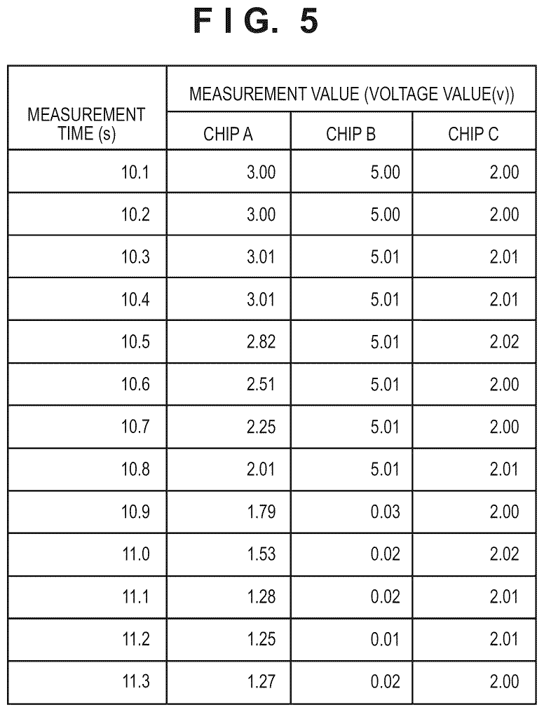

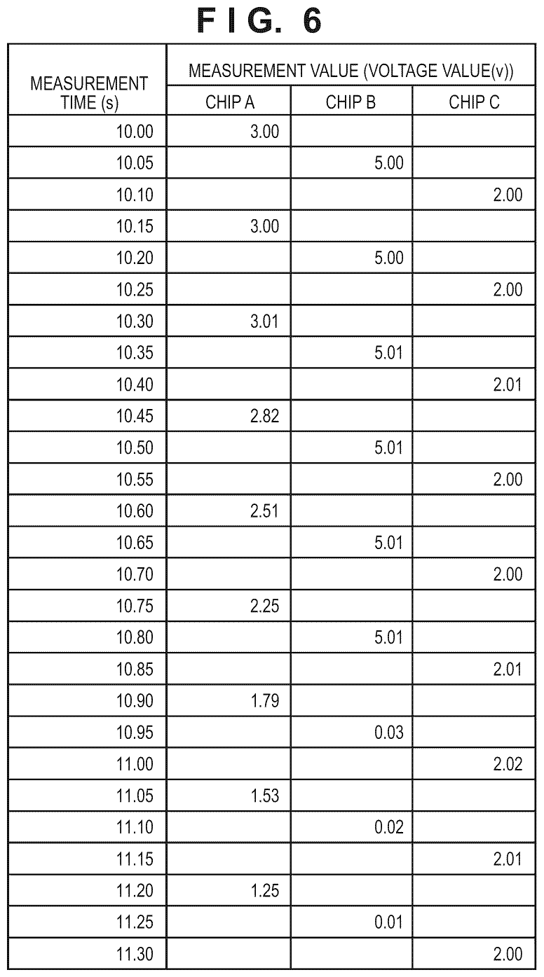

The measurement value storage unit 131 stores history information of measurement values obtained by the coil. More specifically, it can store measurement values (voltage values) with time stamps attached thereto, as shown in FIG. 5 and FIG. 6.

The reference condition storage unit 132 stores a reference condition for defining a steady state which is a state where the plurality of semiconductor chips 1 are placed on the measurement target 4, and which precedes the occurrence of a large change in the relative position between the semiconductor chips. As one example of the reference condition, the following case can be used as the reference condition: a case where a state in which the ranges of fluctuations of measurement values (voltage values) received from all communication-enabled semiconductor chips via the coil are within a predetermined range has continued for a predetermined time period or longer (i.e., a case where a stable state in which the relative position relative to each semiconductor chip has not changed has continued).

The reference value storage unit 133 stores, as a reference value, a voltage value obtained in a case where the reference condition stored in the reference condition storage unit 132 has been satisfied. For example, in a case where a state in which the ranges of fluctuations of measurement values (voltage values) received from all communication-enabled semiconductor chips via the coil are within a predetermined range has continued for a predetermined time period or longer as one example of the reference condition, a measurement value of a signal from each semiconductor chip at the time of satisfaction of this condition can be stored as a reference value. Alternatively, an average value of measurement values during a predetermined time period that precedes the time of satisfaction of this condition can also be stored as a reference value.

The determination condition storage unit 134 stores each of a condition for detecting a change in the relative position, and a condition for detecting a failure in a semiconductor chip. As a condition for determining a change in the relative position, it can be determined that the relative position has changed in a case where a state in which the measurement value is different from a reference value by a predetermined value or more (e.g., 0.5 v or more) has continued for a predetermined time period or longer (e.g., 0.5 seconds or longer), as one example. Note that the condition for determining a change in the relative position is not limited to this, and the condition for determination may be a condition where a change time period until the difference from the reference value becomes equal to or larger than a predetermined value is equal to or longer than a predetermined time period and the voltage value gradually changes. As a condition for detecting a failure in a semiconductor chip, it can be determined that a semiconductor chip has failed in a case where the voltage value of the measurement value has become a near-zero value (e.g., 0.5 v to −0.5 v) within a predetermined time period (e.g., within 0.5 seconds), as one example. Note that the conditions stored in the determination condition storage unit 134 may be written at the time of initial setting of the semiconductor chip, or may be rewritten during operation from outside via the communication unit 112.

In a case where the relative position determination unit 122 has determined that the relative position of the semiconductor chip 1 has changed, the relative position storage unit 135 stores identification information of the semiconductor chip with the changed relative position, time information, and information of the estimated relative position. Storing is not limited to a case where the relative position determination unit 122 has determined that the relative position of the semiconductor chip 1 has changed, and the relative position storage unit 135 may store information of a constantly-estimated relative position together with the time information and the identification information of the semiconductor chip.

In a case where the failure determination unit 123 has determined a failure in the semiconductor chip 1, the failure state storage unit 136 stores the identification information of the semiconductor chip that has been determined to have failed, time information, and failure determination information. Storing is not limited to a case where the failure determination unit 123 has determined that the semiconductor chip 1 has failed, and the failure state storage unit 136 may store information indicating whether there has been a failure, which is constantly determined, together with the time information and the identification information of the semiconductor chip.

The sensing unit 111 obtains information for determining the relative position between the self-semiconductor chip 1 and another semiconductor chip 1 with which communication can be performed via the coil 70, and a failure state of the other semiconductor chip. When the relative position between the self-semiconductor chip 1 and the other semiconductor chip 1 (including the relative distance and the relative angle) has changed, the coupling intensity of inductive coupling of the coils 70 of the semiconductor chips changes, and the voltage value or the voltage amplitude that occurs in the coil 70 change; thus, the sensing unit 111 obtains such voltage information.

The communication unit 112 can communicate with another semiconductor chip 1, the computer 2, and the like, which are apparatuses outside the self-semiconductor chip 1. The communication unit 112 communicates with another semiconductor chip 1, the computer 2, and the like by using the coil 70 as an antenna, for example.

The reference value determination unit 121 determines a reference value used as a point of reference for determining at least one of the relative position and the failure state of the semiconductor chip. Specifically, in a case where the state of the semiconductor chip satisfies the reference condition stored in the reference condition storage unit 132, a measurement value of a reception signal from each of other semiconductor chips with which communication is performed via the coil at the time of satisfaction of this condition is determined as a reference value. Alternatively, an average value of measurement values in a predetermined time period that precedes the time of satisfaction of this condition, or any value between the largest value and the smallest value of measurement values in a predetermined time period that precedes the time of satisfaction of this condition, can be determined as a reference value. The reference value determined by the reference value determination unit 121 is stored into the reference value storage unit 133.

Based on a time-series change in a measurement value, the relative position determination unit 122 determines a change in the relative position between the self-semiconductor chip and another semiconductor chip acting as a communication partner. More specifically, the voltage value obtained by the sensing unit is compared with the reference value stored in the reference value storage unit 133; it is determined that the relative position has not changed from the steady state if the obtained voltage value and the reference value are substantially the same values (the difference therebetween is within a predetermined range), and on the other hand, it is determined that the relative position has changed in a case where the difference between the obtained voltage value and the reference value exceeds the predetermined range and the difference is gradually increasing in time series. Here, the relative position determination unit 122 may detect the relative position, in addition to determining whether there has been a change in the relative position. The result of determination by the relative position determination unit 122 is stored into the relative position storage unit 135.

Here, the relative position determined by the relative position determination unit 122 can include at least one of the relative distance between the semiconductor chips and the relative angle between the semiconductor chips. The voltage value obtained by the sensing unit gradually decreases as the relative distance between the semiconductor chips increases, and the voltage value obtained by the sensing unit gradually increases as the relative distance decreases; thus, a change in the relative position can be detected based on a time-series change in the voltage value.

Furthermore, when the sensing unit uses the coil provided on a flat chip surface of the semiconductor chip as shown in FIG. 2, the voltage value obtained by the sensing unit gradually decreases in a case where the angle of the semiconductor chips gradually change so as to approach an angle along the same plane, and conversely, the voltage value obtained by the sensing unit gradually increases in a case where the angle of the semiconductor chips gradually change so as to approach an angle at which the chip surfaces oppose each other. Therefore, a change in the relative position can be detected based on a time-series change in the voltage value.

The failure determination unit 123 determines a failure in the semiconductor chip on the basis of a time-series change in a measurement value and the failure determination condition of the semiconductor chip stored in the determination condition storage unit 134. Furthermore, the result of determination by the failure determination unit 123 is stored into the failure state storage unit 136.

### Control Flow

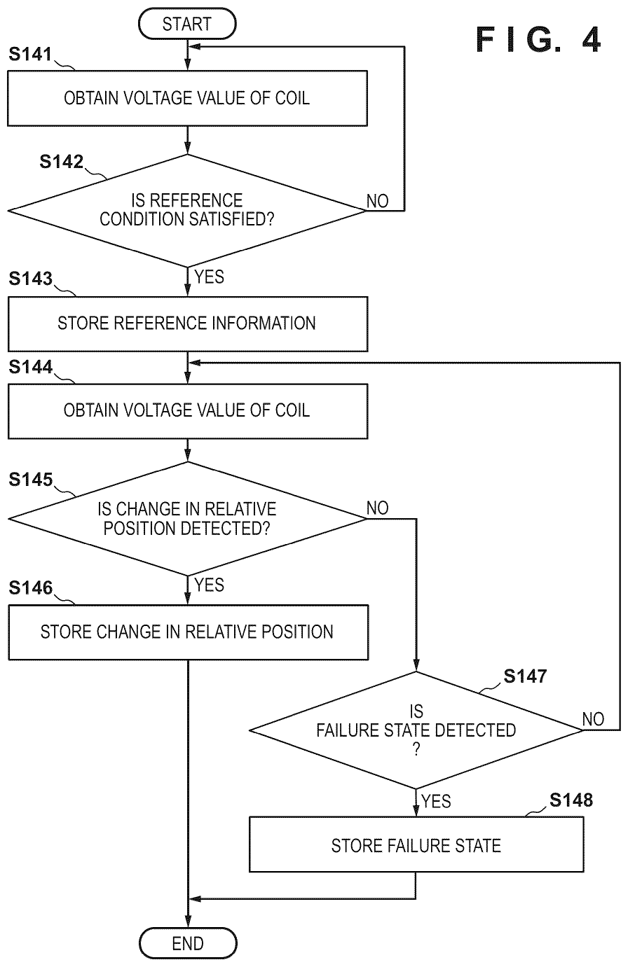

FIG. 4 is a control flow diagram showing the operations of the information processing apparatus. A semiconductor chip 1 obtains a voltage value of the coil with use of the sensing unit 111 (step S141). Next, the reference value determination unit 121 determines whether the state of the semiconductor chip, including the voltage value of the coil, satisfies the reference condition stored in the reference condition storage unit 132 (step S142). If the reference condition is not satisfied, processing returns to step S141, and a voltage value is obtained again. On the other hand, if the reference condition is satisfied, a transition is made to step S143.

In a case where the state of the semiconductor chip satisfies the reference condition, the reference value determination unit 121 determines a reference value used as a point of reference for determining at least one of the relative position and the failure state of the semiconductor chip, and stores the reference value into the reference value storage unit 133 (step S143). Next, the sensing unit 111 obtains a voltage value of the coil (step S144). Next, the relative position determination unit 122 determines a change in the relative position between the self-semiconductor chip and another semiconductor chip (step S145). In a case where a change in the relative position has been detected in step S145, a transition is made to step S146; on the other hand, in a case where a change in the relative position has not been detected in step S145, a transition is made to step S147.

In a case where a change in the relative position has been detected in step S145, the change in the relative position detected by the relative position determination unit 122 is stored into the relative position storage unit 135 (step S146). On the other hand, in a case where a change in the relative position has not been detected in step S145, the failure determination unit 123 determines a failure in the semiconductor chip on the basis of the failure determination condition of the semiconductor chip stored in the determination condition storage unit 134 (step S147). In a case where the failure state of the semiconductor chip has been detected in step S147, a transition is made to step S148.

In a case where the failure state of the semiconductor chip has been detected in step S147, the failure state detected by the failure determination unit 123 is stored into the failure state storage unit 136 (step S148). On the other hand, in a case where the failure state of the semiconductor chip has not been detected in step S147, processing returns to step S144, and a voltage value of the coil is obtained. Next, specific examples of determination processing of the relative position determination unit 122 and the failure determination unit 123 will be described. FIG. 5 is a diagram showing an example of information stored in the measurement value storage unit 131.

The measurement value storage unit 131 stores voltage values of reception signals from nearby semiconductor chips (chips A, B, C) capable of performing wireless communication via inductive coupling or the like as measurement values, together with information of elapsed time periods (measurement times) from the start of the measurement. The example shown in FIG. 5 represents an example of the case where the voltage value of the coil is measured at intervals of 1/10 seconds while adopting a data communication method based on a modulation method capable of performing communication simultaneously with a plurality of semiconductor chips existing nearby (chips A, B, C). As shown in FIG. 5, the semiconductor chip of the present invention is capable of performing communication simultaneously with a plurality of semiconductor chips that are in proximity and measuring a voltage value of a communication signal from each semiconductor chip by recording pieces of identification information and communication frequencies that have been respectively allocated to the plurality of semiconductor chips. The coil 70 of the semiconductor chip 1 can measure the voltage values by receiving wireless signals that use inductive coupling or the like from the plurality of semiconductor chips located nearby (chips A, B, C). FIG. 7 shows a voltage value obtained by the coil 70 via a transmission signal from the nearby semiconductor chip A, and a reception signal generated based on this voltage value. In this way, the coil obtains a voltage value induced in the coil when receiving a wireless signal from a nearby semiconductor chip.

In the example shown in FIG. 5, the voltage values at a time point of an elapsed time period of 10.1 seconds are 3.00 v, 5.00 v, and 2.00 v in the chips A, B, and C, respectively; each voltage value is substantially the same as the reference value stored in the reference value storage unit 133, and the state of each semiconductor chip is the steady state. The voltage values induced by wireless signals from the respective chips in the steady state differ because the relative positions between the respective chips A to C and the self-semiconductor chip differ. As the measured value of the wireless signal of the chip A is larger than that of other chips, it can be estimated that the relative distance to the chip A is shorter than that to other chips, or the relative angle with the chip A is close to an angle at which the chip surfaces oppose each other.

The voltage value induced by the wireless signal from the chip A is 3.00 v at a time point of an elapsed time period of 10.1 seconds, and gradually decreases; at a time point of an elapsed time period of approximately 11.1, the voltage value decreases to 1.28 v. Therefore, this falls under the condition for determining a change in the relative position stored in the determination condition storage unit 134 (a case where a state in which the measurement value is different from the reference value by a predetermined value or more (e.g., 0.5 v or more) has continued for a predetermined time period or longer (e.g., 0.5 seconds or longer)), and it can thus be determined that the relative position between the chip A and the self-semiconductor chip has changed.

Meanwhile, the voltage value induced by the wireless signal from the chip B is approximately 5.00 v during an elapsed time period of 10.1 seconds to 10.8 seconds, but rapidly decreases to 0.03 v (approximately 0 v) at a time point of an elapsed time period of 10.9. Therefore, this falls under the failure determination condition stored in the determination condition storage unit 134 (a condition where the voltage value of the measurement value has become a near-zero value (e.g., 0.5 v to −0.5 v) within a predetermined time period (e.g., within 0.5 seconds)), and it can thus be determined that the chip B has failed.

Furthermore, as the voltage value induced by the wireless signal from the chip C remains at approximately 2.00 v and does not undergo a change larger than 0.5 v during an elapsed time period of 10.1 seconds to 11.3 seconds, it can be determined that neither a change in the relative position nor a failure has occurred in the chip C.

While FIG. 5 shows examples of measurement values of a case that adopts a data communication method based on a modulation method capable of performing communication simultaneously with a plurality of semiconductor chips existing nearby (chips A, B, C), FIG. 6 shows examples of measurement values of a case that adopts near-field communication as a communication method. The example shown in FIG. 6 represents an example of the case where the voltage value of the coil is measured when adopting a data communication method based on a non-modulation method that performs communication with a plurality of semiconductor chips existing nearby (chips A, B, C) with use of near-field communication while switching among communication partners at intervals of 1/20 seconds. The semiconductor chip of the present invention is capable of performing communication with a plurality of semiconductor chips that are in proximity and measuring voltage values of communication signals, as shown in FIG. 6, by recording pieces of identification information and pieces of information of a communication time interval that have been respectively allocated to the plurality of semiconductor chips. Via near-field communication using inductive coupling from a plurality of semiconductor chips located nearby (the chips A, B, C), the coil 70 of the semiconductor chip 1 receives wireless signals from different semiconductor chips at intervals of 1/20 seconds; in this way, voltage values of the wireless signals received from the respective semiconductor chips existing nearby can be measured.

In the example shown in FIG. 6, the voltage values of the chips A, B, and C at time points of elapsed time periods of 10.00 seconds, 10.05 seconds, and 10.10 seconds are 3.00 v, 5.00 v, and 2.00 v, respectively; each voltage value is substantially the same as the reference value stored in the reference value storage unit 133, and the state of each semiconductor chip is the steady state. The voltage values induced by wireless signals from the respective chips in the steady state differ because the relative positions between the respective chips A to C and the self-semiconductor chip differ. As the measured value of the wireless signal of the chip A is larger than that of other chips, it can be estimated that the relative distance to the chip A is shorter than that to other chips, or the relative angle with the chip A is close to an angle at which the chip surfaces oppose each other.

The voltage value induced by the wireless signal from the chip A is 3.00 v at a time point of an elapsed time period of 10.00 seconds, and gradually decreases; at a time point of an elapsed time period of approximately 11.20, the voltage value decreases to 1.25 v. Therefore, this falls under the condition for determining a change in the relative position stored in the determination condition storage unit 134 (a case where a state in which the measurement value is different from the reference value by a predetermined value or more (e.g., 0.5 v or more) has continued for a predetermined time period or longer (e.g., 0.5 seconds or longer)), and it can thus be determined that the relative position between the chip A and the self-semiconductor chip has changed.

Meanwhile, the voltage value induced by the wireless signal from the chip B is approximately 5.00 v during an elapsed time period of 10.05 seconds to 10.80 seconds, but rapidly decreases to 0.03 v (approximately 0 v) at a time point of an elapsed time period of 10.95. Therefore, this falls under the failure determination condition stored in the determination condition storage unit 134 (a condition where the voltage value of the measurement value has become a near-zero value (e.g., 0.5 v to −0.5 v) within a predetermined time period (e.g., within 0.5 seconds)), and it can thus be determined that the chip B has failed.

Furthermore, as the voltage value induced by the wireless signal from the chip C remains at approximately 2.00 v and does not undergo a change larger than 0.5 v during an elapsed time period of 10.10 seconds to 11.30 seconds, it can be determined that neither a change in the relative position nor a failure has occurred in the chip C.

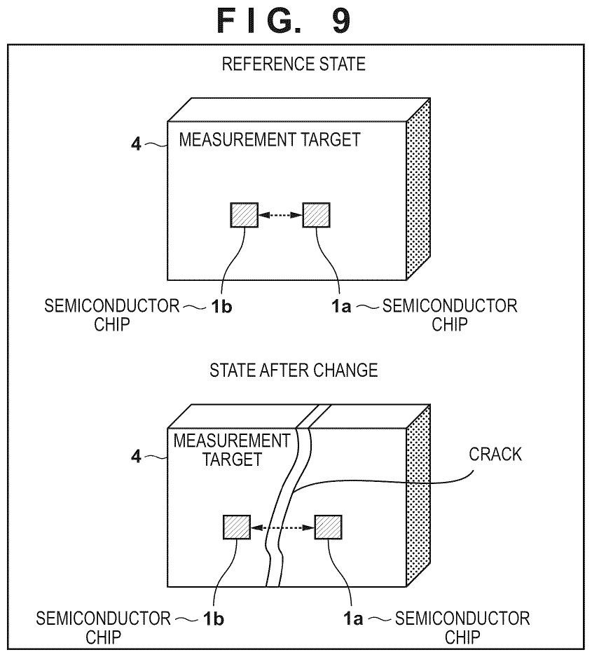

FIG. 8 and FIG. 9 are diagrams showing examples of application of the information processing apparatus. The information processing apparatus of the present invention with a function of determining a change in the relative position between semiconductor chips can be used in, for example, determining a movement of a movable member, such as a door shown in FIG. 8. As shown in the upper illustration of FIG. 8, one semiconductor chip 1a is mounted on a movable member, and the other semiconductor chip 1b is mounted on a fixed member. In a reference state, the movable member is stationary in a state where the semiconductor chips 1a and 1b are in proximity to each other; therefore, measurement values obtained in each semiconductor chip in this reference state are stored into the reference value storage unit as reference values. Here, in a case where the movable member has moved and is placed in a post-change state as shown in the lower illustration of FIG. 8, the relative position between the semiconductor chip 1a and the semiconductor chip 1b changes, and thus the semiconductor chips 1a and 1b can detect the change in the relative position on the basis of voltage values of the coils. That is to say, the fact that the door has changed from a closed state to an open state can be detected.

Furthermore, using a construction member such as concrete, wood, asphalt, steel frames, or the like, such as a door shown in FIG. 9 for example, as a measurement target 4, the information processing apparatus of the present invention can be placed inside or on a surface of the measurement target 4 and can be used in determining a state of the construction member. The upper illustration of FIG. 9 shows a reference state, and measurement values in this reference state are stored as reference values in each semiconductor chip. Then, if a crack or the like has occurred in the measurement target 4 as shown in the lower illustration of FIG. 9, the relative distance between the semiconductor chips increases, and thus the semiconductor chips 1a and 1b can detect a change in the relative position on the basis of voltage values of the coils. That is to say, a crack or the like that occurs in the measurement target 4 can be detected.

### Another Example of Sensing Processing Based on Received Wireless Signal

The processing described with reference to FIG. 4 is one example of sensing processing that a semiconductor chip 1 executes based on a wireless signal received from another semiconductor chip 1. The sensing processing is processing in which the semiconductor chip 1 obtains an evaluation value indicating the quality of a wireless signal, and determines the state of at least one of the semiconductor chip 1 and another semiconductor chip 1 on the basis of the obtained evaluation value. That is to say, the sensing processing includes processing for obtaining an evaluation value (evaluation value obtainment processing), and processing for determining a state (state determination processing). In the example of FIG. 4, the semiconductor chip 1 obtains, as an evaluation value indicating the quality of the wireless signal, a voltage value induced in the coil 70 by a wireless signal (one example of a measurement value of the wireless signal).

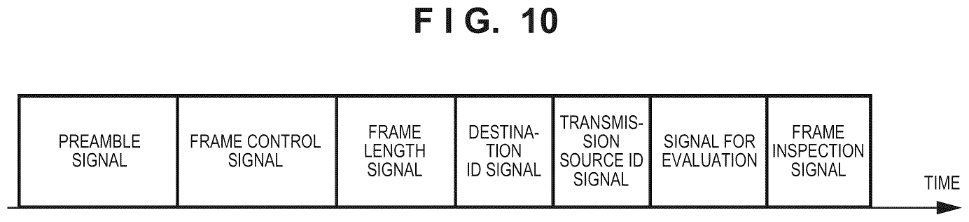

With reference to FIG. 10 to FIG. 15, the following describes another example of the sensing processing that the semiconductor chip 1 executes based on a wireless signal received from another semiconductor chip 1.

Here, an operation mode of the semiconductor chip 1 for enabling the sensing processing is referred to as a sensing mode. In the sensing mode, the semiconductor chip 1 transmits a wireless signal for the sensing processing to another adjacent semiconductor chip 1. For example, in the information processing apparatus shown in FIG. 2, the semiconductor chip 1b transmits a wireless signal for the sensing processing to the semiconductor chip 1a, and the semiconductor chip 1a executes the sensing processing on the basis of the received wireless signal. Also, the semiconductor chip 1a transmits a wireless signal for the sensing processing to the semiconductor chip 1b, and the semiconductor chip 1b executes the sensing processing on the basis of the received wireless signal.

A transmission timing of a wireless signal for the sensing processing has been determined in advance, and the semiconductor chip 1 is aware of a timing at which a wireless signal is transmitted from another semiconductor chip 1 to itself. For example, in the information processing apparatus shown in FIG. 2, the semiconductor chip 1b transmits a wireless signal for the sensing processing to the semiconductor chip 1a every 0.2 seconds, like 0.2 seconds, 0.4 seconds, 0.6 seconds, . . . after the start of the sensing mode. Furthermore, the semiconductor chip 1a transmits a wireless signal for the sensing processing to the semiconductor chip 1b every 0.2 seconds, at the timings that are off the timings in the semiconductor chip 1a by 0.1 seconds, like 0.1 seconds, 0.3 seconds, 0.5 seconds, . . . after the start of the sensing mode.

A wireless signal for the sensing processing is transmitted as a wireless signal frame with a predetermined frame format.

FIG. 10 is a diagram showing an example of a format of a wireless signal frame for the sensing processing. In the example of FIG. 10, the wireless signal frame for the sensing processing has a frame format including a preamble signal, a frame control signal, a frame length signal, a destination ID signal, a transmission source ID signal, a signal for evaluation, and a frame inspection signal.

The preamble signal is a predetermined signal sequence (e.g., a bit string of a specific pattern, such as “101101”) indicating the existence of the wireless signal frame. The semiconductor chip 1 can detect the transmission of the wireless signal frame from another semiconductor chip 1 by detecting the existence of the preamble signal.

The frame control signal is a signal indicating a type of the wireless signal frame. Types of the wireless signal frame include “information frame”, “control frame”, “management frame”, “frame for evaluation”, and so forth. In the case of the wireless signal frame for the sensing processing, information indicating the frame for evaluation is set as a type in the frame control signal. In other words, in a case where a type of a wireless signal frame is the frame for evaluation, this wireless signal frame is used as the wireless signal frame for the sensing processing.

The frame length signal is a control signal including information on the length of the wireless signal frame.

The destination ID signal indicates identification information (ID) of the semiconductor chip 1 corresponding to a destination of the wireless signal frame. For example, the destination ID signal in the wireless signal frame transmitted from the semiconductor chip 1b to the semiconductor chip 1a includes an address of the semiconductor chip 1a as an ID of the semiconductor chip 1a.

The transmission source ID signal indicates identification information (ID) of the semiconductor chip 1 that transmits the wireless signal frame. For example, the transmission source ID signal in the wireless signal frame transmitted from the semiconductor chip 1b to the semiconductor chip 1a includes an address of the semiconductor chip 1b as an ID of the semiconductor chip 1b.

The signal for evaluation is a signal used by the semiconductor chip 1 to obtain an evaluation value of the wireless signal. The signal for evaluation is a predetermined signal sequence (e.g., a bit string of a specific pattern, such as “11100111”). For example, the semiconductor chip 1 can obtain the evaluation value of the wireless signal by comparing a known signal for evaluation with a signal for evaluation actually received (the details of the evaluation value obtainment processing will be described later).

The frame inspection signal is a signal for inspecting whether there is an error in the received wireless signal frame. For example, a cyclic redundancy check (CRC) code is used as the frame inspection signal. Upon receiving the frame inspection signal, the semiconductor chip 1 completes the reception of the wireless signal frame.

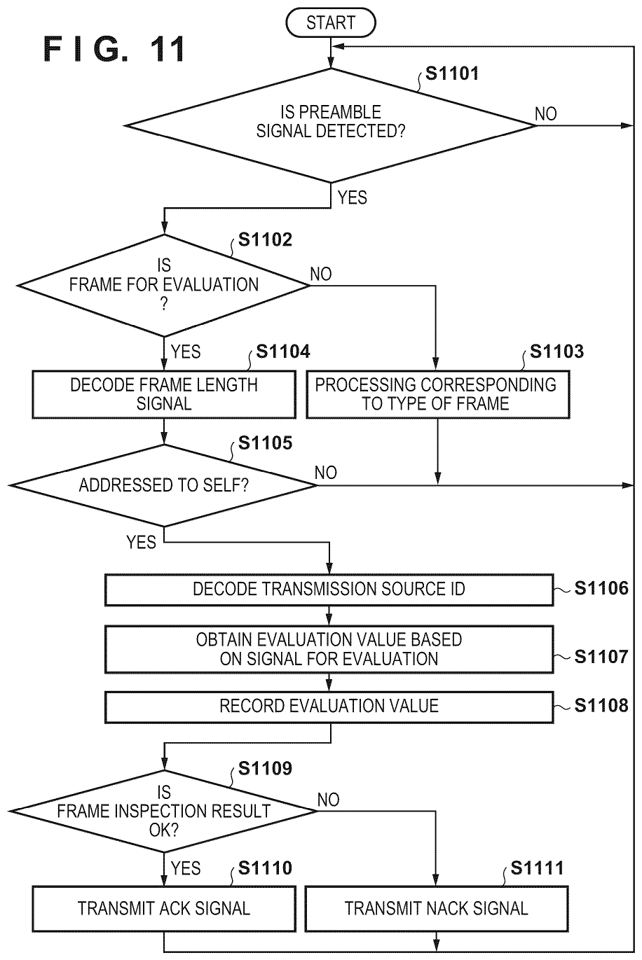

FIG. 11 is a flowchart of processing for obtaining an evaluation value of a wireless signal that a semiconductor chip 1 has received from another semiconductor chip 1 (the evaluation value obtainment processing included in the sensing processing). As an example, the following describes a case where the semiconductor chip 1b transmits a wireless signal for the sensing processing to the semiconductor chip 1a, and the semiconductor chip 1a obtains an evaluation value of the received wireless signal in the information processing apparatus of FIG. 2.

Note that in the sensing mode, the transmission/reception circuit 80a of the semiconductor chip 1a supplies a pulse sequence corresponding to a voltage value of the coil 70a induced by the received wireless signal to the processor 10a. Therefore, for example, the reception signal (pulse sequence) shown in the bottom tier of FIG. 7, which corresponds to the voltage value shown in the middle tier of FIG. 7, is supplied to the processor 10a. Here, as stated earlier, the sensing unit 111 can be realized by the processor 10a executing a program stored in the memory 20a. Therefore, the sensing unit 111 can obtain the pulse sequence supplied from the transmission/reception circuit 80a, and decodes the wireless signal by sampling the obtained pulse sequence in a predetermined sampling period; as a result, a binary signal sequence (bit string) denoted by 1 (High) or 0 (Low) can be obtained. Thus, when the semiconductor chip 1b has transmitted a wireless signal to the semiconductor chip 1a in the sensing mode, the sensing unit 111 of the semiconductor chip 1a can obtain a signal sequence indicated by the wireless signal.

In step S1101, the sensing unit 111 of the semiconductor chip 1a determines whether a known preamble signal has been detected from a wireless signal (i.e., whether the adjacent semiconductor chip 1b is transmitting a wireless signal frame). Specifically, the sensing unit 111 compares a signal sequence obtained by decoding a pulse sequence supplied from the transmission/reception circuit 80a with the known preamble signal, and determines that the known preamble signal has been detected from the wireless signal in a case where they match. The sensing unit 111 repeats processing of step S1101 until the preamble signal is detected. Once the preamble signal has been detected, processing proceeds to step S1102.

In step S1102, the sensing unit 111 decodes a frame control signal that follows the preamble signal, and determines whether the type of the wireless signal frame is a frame for evaluation. In a case where the type of the wireless signal frame is the frame for evaluation, processing proceeds to step S1104; otherwise, processing proceeds to step S1103.

In step S1103, the sensing unit 111 executes processing corresponding to the type of the wireless signal frame (processing different from the sensing processing) as appropriate. Thereafter, processing returns to step S1101.

In step S1104, the sensing unit 111 decodes a frame length signal, and checks the length of the wireless signal frame.

In step S1105, the sensing unit 111 decodes a destination ID signal, and determines whether the wireless signal frame is addressed to itself (whether a destination ID is the address of the semiconductor chip 1a ). In a case where the wireless signal frame is addressed to itself, processing proceeds to step S1106; otherwise, processing returns to step S1101.

In step S1106, the sensing unit 111 decodes a transmission source ID signal, and obtains an ID (address) of the semiconductor chip 1b, which is the transmission source of the wireless signal frame.

In step S1107, the sensing unit 111 obtains an evaluation value of the wireless signal on the basis of a signal for evaluation. For example, a value based on a measurement value (e.g., a voltage value) of the signal for evaluation, or a value based on the number of bit errors in the signal for evaluation, can be used as the evaluation value of the wireless signal. Note that the evaluation value of the wireless signal is not limited to these examples, and any type of value can be used thereas as long as it acts as an indicator of the quality of the wireless signal, and it can be used in determining a state of at least one of the semiconductor chip 1a (the destination of the wireless signal) and the semiconductor chip 1b (the transmission source of the wireless signal).

In a case where the value based on the voltage value of the signal for evaluation is used as the evaluation value of the wireless signal, the sensing unit 111 obtains, for example, a voltage value of a part of the wireless signal frame corresponding to the signal for evaluation, which has been measured by the transmission/reception circuit 80a, as the evaluation value.

In a case where the value based on the number of bit errors in the signal for evaluation is used as the evaluation value of the wireless signal, the sensing unit 111 counts the number of bit errors in the signal for evaluation by, for example, comparing the decoded signal for evaluation with a known signal for evaluation, and obtains the number of bit errors as the evaluation value. In this case, it is considered that the quality of the wireless signal is more favorable as the number of bit errors decreases. Alternatively, the sensing unit 111 may calculate a bit error rate on the basis of the number of bits in the signal for evaluation and the number of bit errors, and obtain the bit error rate as the evaluation value based on the number of bit errors in the signal for evaluation.

Note that as has been described with reference to FIG. 4, in a case where the voltage value of the wireless signal is used as the evaluation value, the sensing unit 111 can obtain a voltage value of any wireless signal other than the signal for evaluation as the evaluation value. However, in this case, when the voltage value of the coil 70a has fluctuated due to, for example, noise, there is a possibility that the sensing unit 111 misidentifies the noise as a wireless signal and obtains a voltage value of the noise as the evaluation value of the wireless signal. On the other hand, according to processing of FIG. 11, the sensing unit 111 checks that the wireless signal frame addressed to the semiconductor chip 1a has been actually received from the semiconductor chip 1b, and thereafter can obtain the voltage value of the known signal for evaluation located at a known position within the wireless signal frame. This can reduce the possibility of erroneously obtaining a voltage value that does not correspond to the wireless signal actually transmitted (e.g., a voltage value attributed to noise) as the evaluation value.

In step S1108, the sensing unit 111 records the evaluation value obtained in step S1107 in the measurement value storage unit 131. That is to say, in processing shown in FIG. 11, the measurement value storage unit 131 plays a role as an evaluation value storage unit that stores the evaluation value. At this time, the sensing unit 111 records the reception time of the wireless signal frame from which the evaluation value has been obtained, and the transmission source ID of the wireless signal frame, in association with the evaluation value. In this way, pieces of information indicating a time-series change in the evaluation value corresponding to a specific transmission source are accumulated in the measurement value storage unit 131.

In step S1109, the sensing unit 111 decodes a frame inspection signal, and determines whether the wireless signal frame has been received without error. In a case where the wireless signal frame has been received without error (in a case where the frame inspection result is OK), processing proceeds to step S1110; otherwise, processing proceeds to step S1111.

In step S1110, the sensing unit 111 transmits an Acknowledgement (ACK) signal to the semiconductor chip 1b, which is the transmission source of the wireless signal frame. Thereafter, processing returns to step S1101.

In step S1111, the sensing unit 111 transmits a Negative ACK (NACK) signal to the semiconductor chip 1b, which is the transmission source of the wireless signal frame. Thereafter, processing returns to step S1101.

Note that the result of the frame inspection in step S1109 (a value indicating a success or a failure of the frame inspection) may be used as another example of the evaluation value of the wireless signal). In this case, after performing the frame inspection, the sensing unit 111 records the result thereof in the measurement value storage unit 131 as the evaluation value.

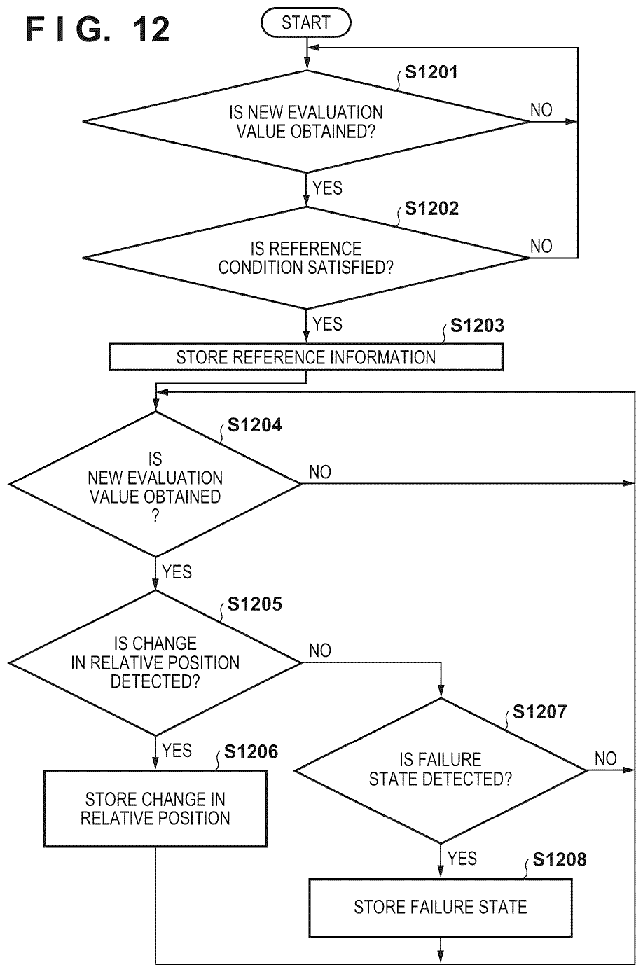

Next, the state determination processing included in the sensing processing will be described with reference to FIG. 12. The state determination processing of FIG. 12 is executed in parallel with the evaluation value obtainment processing of FIG. 11. Therefore, an evaluation value is obtained repeatedly in parallel with the state determination processing. As an example, the following describes a case where the semiconductor chip 1b transmits a wireless signal for the sensing processing to the semiconductor chip 1a, and the semiconductor chip 1a obtains an evaluation value of the received wireless signal in the information processing apparatus of FIG. 2, similarly to the description of FIG. 11.

In step S1201, the sensing unit 111 of the semiconductor chip 1a determines whether a new evaluation value has been obtained through the evaluation value obtainment processing. The sensing unit 111 repeats processing of step S1201 until a new evaluation value is obtained. Once a new evaluation value has been obtained, processing proceeds to step S1202.

In step S1202, similarly to step S142 of FIG. 4, the reference value determination unit 121 determines whether the state of the semiconductor chip 1a, including the evaluation value, satisfies the reference condition stored in the reference condition storage unit 132. The reference condition is not limited in particular, and is determined as appropriate in accordance with the type of the evaluation value used. For example, in a case where a voltage value of the coil 70a is used as the evaluation value, the reference condition that is the same as the reference condition used in step S142 of FIG. 4 can be used in step S1202. In a case where the reference condition is satisfied, processing proceeds to step S1203, whereas in a case where the reference condition is not satisfied, processing returns to step S1201.

In step S1203, similarly to step S143 of FIG. 4, the reference value determination unit 121 determines a reference value (reference information) used as a point of reference for determining a state of at least one of the semiconductor chip 1a and the semiconductor chip 1b (e.g., at least one of the relative position between the semiconductor chip 1a and the semiconductor chip 1b, and a failure state of the semiconductor chip 1b), and stores the reference value into the reference value storage unit 133.

In step S1204, the sensing unit 111 determines whether a new evaluation value has been obtained through the evaluation value obtainment processing. The sensing unit 111 repeats processing of step S1204 until a new evaluation value is obtained. Once a new evaluation value has been obtained, processing proceeds to step S1205.

In step S1205, similarly to step S145 of FIG. 4, the relative position determination unit 122 determines a change in the relative position between the semiconductor chip 1a and the semiconductor chip 1b on the basis of the condition for determining a change in the relative position stored in the determination condition storage unit 134. The condition for determining a change in the relative position is not limited in particular, and is determined as appropriate in accordance with the type of the evaluation value used. For example, in a case where a voltage value of the coil 70a is used as the evaluation value, the determination condition that is the same as the determination condition used in step S145 of FIG. 4 can be used in step S1205. In a case where a change in the relative position has been detected, processing proceeds to step S1206, whereas in a case where a change in the relative position has not been detected, processing proceeds to step S1207.

In step S1206, similarly to step S146 of FIG. 4, the relative position determination unit 122 stores the detected change in the relative position into the relative position storage unit 135. Furthermore, the relative position determination unit 122 may notify the computer 2 of the change in the relative position with use of the communication unit 112. Thereafter, processing returns to step S1204.

In step S1207, similarly to step S147 of FIG. 4, the failure determination unit 123 determines a failure in the semiconductor chip 1b on the basis of the failure determination condition stored in the determination condition storage unit 134. The failure determination condition is not limited in particular, and is determined as appropriate in accordance with the type of the evaluation value used. For example, in a case where a voltage value of the coil 70a is used as the evaluation value, the failure determination condition that is the same as the failure determination condition used in step S147 of FIG. 4 can be used in step S1207. In a case where a failure in the semiconductor chip 1b has been detected, processing proceeds to step S1208, whereas in a case where a failure in the semiconductor chip 1b has not been detected, processing returns to step S1204.

In step S1208, similarly to step S148 of FIG. 4, the failure determination unit 123 stores the detected failure state into the failure state storage unit 136. Furthermore, the failure determination unit 123 may notify the computer 2 of the failure state with use of the communication unit 112. Thereafter, processing returns to step S1204.

Note that as described above in connection with processing of step S145 of FIG. 4, examples of the condition for determining a change in the relative position include a condition where a state in which the measurement value is different from the reference value by a predetermined value or more (e.g., 0.5 v or more) has continued for a predetermined time period or longer (e.g., 0.5 seconds or longer). This determination condition is based on the reference value and a time-series change in the measurement value (evaluation value). However, as stated earlier, the condition for determining a change in the relative position is not limited in particular; for example, a determination condition that is not dependent on the reference value may be used. Furthermore, a determination condition that is based on one measurement value (evaluation value) obtained most recently, rather than a time-series change in the measurement value (evaluation value), may be used. As one example, assume a case where the evaluation value is the number of bit errors in the signal for evaluation, and the condition for determining a change in the relative position is a condition where the number of bit errors is equal to or larger than a predetermined number (e.g., 2 bits). In this case, when the failure determination condition is not dependent on the reference value, either, the state determination processing of FIG. 12 can be started from step S1204. Then, in step S1205, the relative position determination unit 122 determines whether or not the number of bit errors, which is the evaluation value, is equal to or larger than the predetermined number, and detects a change in the relative position in a case where the number of bit errors is equal to or larger than the predetermined number.

As another example of the condition for determining a change in the relative position, it is possible to use a condition where a state in which the number of bit errors, which is the evaluation value, is equal to or larger than the predetermined number (e.g., two bits) has continued for a predetermined time period or longer (e.g., 0.5 seconds or longer). This determination condition is not dependent on the reference value, but is based on a time-series change in the evaluation value. In this case, when the failure determination condition is not dependent on the reference value, either, the state determination processing of FIG. 12 can be started from step S1204. Then, in step S1205, the relative position determination unit 122 determines whether or not the state in which the number of bit errors, which is the evaluation value, is equal to or larger than the predetermined number has continued for the predetermined time period or longer; in a case where the state in which the number of bit errors is equal to or larger than the predetermined number has continued for the predetermined time period or longer, a change in the relative position is detected.

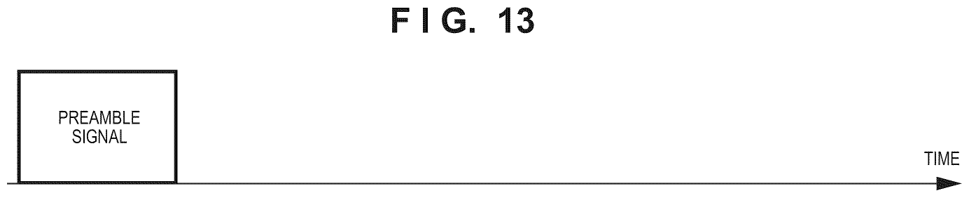

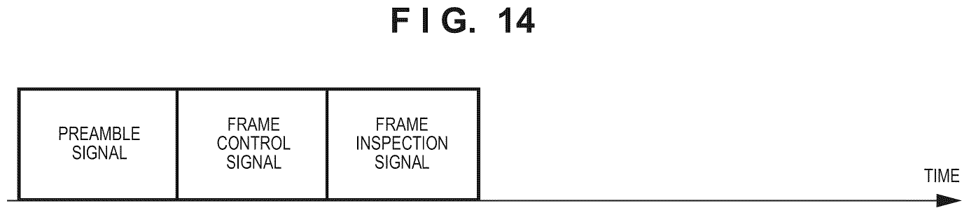

Furthermore, according to the above description, it is assumed that a wireless signal frame for the sensing processing has the format shown in FIG. 10. However, the format of the wireless signal frame for the sensing processing is not limited to the format shown in FIG. 10, and may be a format shown in FIG. 13 or FIG. 14, for example.

In the case of FIG. 13, the sensing unit 111 determines whether a preamble signal has been detected through processing similar to step S1101 of FIG. 11. In a case where the preamble signal has been detected, the sensing unit 111 obtains an evaluation value of a wireless signal through processing similar to step S1107 of FIG. 11. Note that in a case where the wireless signal frame of FIG. 10 is used, the evaluation value is obtained based on a part corresponding to the signal for evaluation (one example of “specific signal part”); however, in a case where the wireless signal frame of FIG. 13 is used, the sensing unit 111 obtains the evaluation value on the basis of a part corresponding to the preamble signal (another example of “specific signal part”).

Note that when bit errors have occurred in the preamble signal, the preamble signal is not detected in step S1101. For this reason, the sensing unit 111 may obtain the evaluation value by making use of the fact that the timing of transmission of the wireless signal frame for the sensing processing by the semiconductor chip 1b in the sensing mode is known. In this case, the sensing unit 111 can obtain the evaluation value on the basis of a wireless signal transmitted at the known transmission timing of the wireless signal frame, irrespective of whether the preamble signal has been detected. For example, even in a case where bit errors have occurred in the preamble signal, the sensing unit 111 can obtain the evaluation value that is based on the number of bit errors by comparing a signal sequence indicated by the wireless signal transmitted at the known transmission timing with a known preamble signal.

In the case of FIG. 14, the sensing unit 111 can obtain the evaluation value on the basis of a preamble signal included in the wireless signal frame, similarly to the case of FIG. 13. Also, as the wireless signal frame of FIG. 14 includes a frame inspection signal, the sensing unit 111 can determine whether the wireless signal frame has been received without error through processing similar to step S1109 of FIG. 11. Therefore, the sensing unit 111 may obtain the result of the frame inspection (a value indicating a success or a failure of the frame inspection) as the evaluation value.

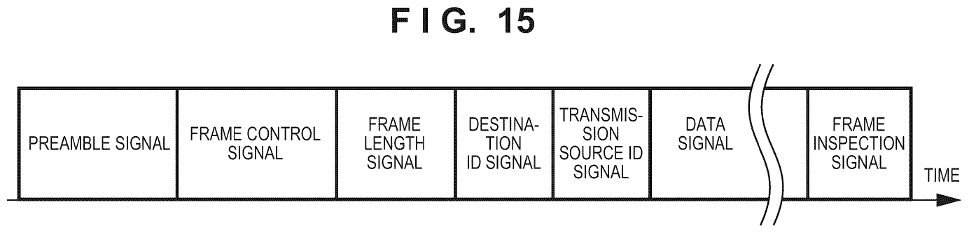

Furthermore, there are cases where information data to be transmitted to the semiconductor chip 1a arises while the semiconductor chip 1b is operating in the sensing mode. In such cases, the semiconductor chip 1b may transmit an information frame shown in FIG. 15 to the semiconductor chip 1a at a timing at which a wireless signal frame for the sensing processing is to be transmitted. Although the format of the information frame is similar to the format of the frame for evaluation shown in FIG. 10, information indicating the information frame is set as a type in a frame control signal. Furthermore, the information frame includes a data signal indicating information data, in place of a signal for evaluation. The information frame includes a preamble signal and a frame inspection signal, similarly to the wireless signal frame shown in FIG. 14. Therefore, in a case where the information frame has been transmitted from the semiconductor chip 1b to the semiconductor chip 1a, the sensing unit 111 can obtain the evaluation value on the basis of the preamble signal, and obtain the result of the frame inspection as the evaluation value, similarly to the case of FIG. 14.

### Example of Sensing Processing Based on Transmitted Wireless Signal

As stated earlier, the processing described with reference to FIG. 4 is one example of sensing processing that a semiconductor chip 1 executes based on a wireless signal received from another semiconductor chip 1. That is to say, the example of FIG. 4 adopts a configuration in which the semiconductor chip 1 on the receiving side of the wireless signal executes the sensing processing. On the other hand, it is also possible to adopt a configuration in which the semiconductor chip 1 on the transmitting side of the wireless signal executes the sensing processing.

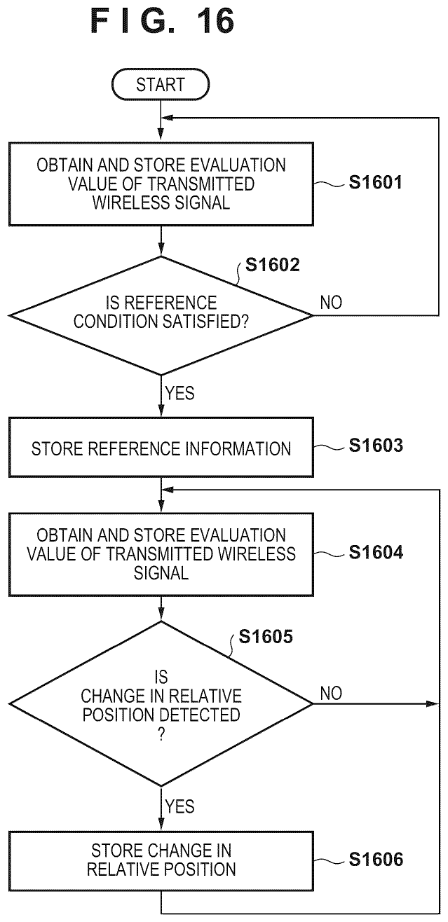

With reference to FIG. 16, the following describes a configuration in which the semiconductor chip 1 on the transmitting side of a wireless signal executes the sensing processing. FIG. 16 is a flowchart of sensing processing that a semiconductor chip 1 executes based on a wireless signal transmitted to another semiconductor chip 1. As an example, the following describes a case where, when the semiconductor chip 1b transmits a wireless signal to the semiconductor chip 1a in the information processing apparatus of FIG. 2, the sensing processing is executed based on the wireless signal transmitted by the semiconductor chip 1b.

Note that during the sensing processing of FIG. 16, the communication unit 112 of the semiconductor chip 1b repeatedly transmits a wireless signal to the semiconductor chip 1a with use of the transmission/reception circuit 80b. Although the transmission timing of the wireless signal is not limited in particular, for example, the communication unit 112 may transmit the wireless signal at the transmission timing that is the same as the transmission timing in the example of FIG. 4.

In step S1601, the sensing unit 111 of the semiconductor chip 1b obtains an evaluation value of the transmitted wireless signal, and stores the obtained evaluation value into the measurement value storage unit 131.

For example, a current value flowing through the coil 70b (and the transmission/reception circuit 80b connected to the coil 70b) at the time of transmission of the wireless signal can be used as the evaluation value. When a voltage corresponding to the transmitted wireless signal is applied to the coil 70b, a voltage is induced in the coil 70a of the semiconductor chip 1a through electromagnetic induction. As a result, a current flows through the coil 70a (and the transmission/reception circuit 80a connected to the coil 70a). Here, for example, in a case where the coupling coefficient between the coil 70a and the coil 70b has decreased and the quality of wireless communication has deteriorated, the voltage induced in the coil 70a of the semiconductor chip 1a decreases, and thus the current flowing through the coil 70a also drops. As a result, the current flowing through the coil 70b of the semiconductor chip 1b becomes larger than that of a case where the quality of wireless communication is favorable. Therefore, the current value which flows through the coil 70b, and which is measured at the time of transmission of the wireless signal, can be used as an evaluation value indicating the quality of the transmitted wireless signal.

As another example of the evaluation value, a voltage value measured in the coil 70b (e.g., measured at the site of connection between the transmission/reception circuit 80b and the coil 70b) can be used. When a voltage corresponding to the transmitted wireless signal is applied to the coil 70b, a voltage is induced in the coil 70a of the semiconductor chip 1a through electromagnetic induction. In this case, the voltage at the site of connection between the transmission/reception circuit 80b and the coil 70b drops due to reflection components of the voltage induced in the coil 70a. Here, for example, in a case where the coupling coefficient between the coil 70a and the coil 70b has decreased and the quality of wireless communication has deteriorated, the voltage induced in the coil 70a of the semiconductor chip 1a decreases, and thus a voltage drop in the site of connection between the transmission/reception circuit 80b and the coil 70b becomes small. That is to say, in a case where the quality of wireless communication has decreased, the voltage value of the coil 70b (the voltage value measured in the coil 70b) becomes larger than that of a case where the quality of wireless communication is favorable. Therefore, the voltage value measured at the time of transmission of the wireless signal at the site of connection between the transmission/reception circuit 80b and the coil 70b (the voltage value of the coil 70b) can be used as the evaluation value indicating the quality of the transmitted wireless signal.

Furthermore, in a case where the wireless signal frame shown in FIG. 10, FIG. 14, or FIG. 15 is transmitted as the wireless signal for the sensing processing, the semiconductor chip 1a that has received the wireless signal frame transmits an ACK signal or a NACK signal to the semiconductor chip 1b in accordance with the result of the frame inspection based on a frame inspection signal. In this case, the sensing unit 111 of the semiconductor chip 1b may obtain information indicating whether the ACK signal has been received as the evaluation value. In a case where the ACK signal has been received, it is considered that the quality of the wireless signal is more favorable than that of a case where the ACK signal has not been received (a case where a NACK signal has been received, or a case where neither the ACK signal nor the NACK signal has been received).

In step S1602, similarly to step S142 of FIG. 4, the reference value determination unit 121 determines whether the state of the semiconductor chip 1b, including the evaluation value, satisfies the reference condition stored in the reference condition storage unit 132. The reference condition is not limited in particular, and is determined as appropriate in accordance with the type of the evaluation value used. As one example of the reference condition, a case where a state in which the range of fluctuation of the evaluation value is within a predetermined range has continued for a predetermined time period or longer (i.e., a case where a stable state in which the relative position between the semiconductor chip 1a and the semiconductor chip 1b undergoes no change has continued) can be used as the reference condition.

In step S1603, similarly to step S143 of FIG. 4, the reference value determination unit 121 determines a reference value (reference information) used as a point of reference for determining the relative position between the semiconductor chip 1a and the semiconductor chip 1b, and stores the reference value into the reference value storage unit 133.

In step S1604, the sensing unit 111 obtains an evaluation value of a transmitted wireless signal, and stores the obtained evaluation value into the measurement value storage unit 131.

In step S1605, similarly to step S145 of FIG. 4, the relative position determination unit 122 determines a change in the relative position between the semiconductor chip 1a and the semiconductor chip 1b on the basis of the condition for determining a change in the relative position stored in the determination condition storage unit 134. The condition for determining a change in the relative position is not limited in particular, and is determined as appropriate in accordance with the type of the evaluation value used. For example, in a case where the evaluation value is a voltage value of the coil 70b, a condition where a state in which the voltage value is different from the reference value by a predetermined value or more (e.g., 0.5 v or more) has continued for a predetermined time period or longer (e.g., 0.5 seconds or longer) can be used as one example of the condition for determining a change in the relative position. In a case where a change in the relative position has been detected, processing proceeds to step S1606, whereas in a case where a change in the relative position has not been detected, processing returns to step S1604.

Note that similarly to the case of FIG. 12, a condition that is not dependent on the reference value may be used as the condition for determining a change in the relative position. Furthermore, similarly to the case of FIG. 12, a determination condition that is based on one evaluation value obtained most recently, rather than a time-series change in the evaluation value, may be used.

In step S1606, similarly to step S146 of FIG. 4, the relative position determination unit 122 stores the detected change in the relative position into the relative position storage unit 135. Thereafter, processing returns to step S1604.

### Example in Which Different Semiconductor Chips 1 Share Evaluation Value Obtainment Processing and State Determination Processing

Different semiconductor chips 1 may share the execution of the evaluation value obtainment processing and the state determination processing included in the sensing processing. For example, assume a case where the semiconductor chip 1b transmits a wireless signal for the sensing processing to the semiconductor chip 1a in the information processing apparatus of FIG. 2. In this case, the sensing unit 111 of the semiconductor chip 1a can obtain an evaluation value of the received wireless signal in accordance with any evaluation value obtainment processing pertaining to various examples of the sensing processing described above. Next, the sensing unit 111 of the semiconductor chip 1a transmits the obtained evaluation value to the semiconductor chip 1b. A method of transmission of the evaluation value is not limited in particular; as one example, the sensing unit 111 of the semiconductor chip 1a may include the evaluation value in an ACK signal or a NACK signal when transmitting the ACK signal or the NACK signal to the semiconductor chip 1b in accordance with the result of the frame inspection of a wireless signal frame.

The sensing unit 111 of the semiconductor chip 1b records the evaluation value received from the semiconductor chip 1a in the measurement value storage unit 131. Then, the sensing unit 111 of the semiconductor chip 1b can execute state determination processing on the basis of the evaluation value received from the semiconductor chip 1a in accordance with any state determination processing pertaining to various examples of the sensing processing described above.

In a case where different semiconductor chips 1 share the evaluation value obtainment processing and the state determination processing as described above, the semiconductor chip 1a that does not execute the state determination processing need not include constituents for the state determination processing (the state determination unit 120 and various types of storage units indicated by reference signs 131 to 136). Therefore, the configuration of the semiconductor chip 1a can be simplified. Furthermore, in a case where the information processing apparatus includes one or more semiconductor chips other than the semiconductor chip 1a and the semiconductor chip 1b, the state determination processing can be executed while compiling evaluation values of wireless signals among the plurality of semiconductor chips 1 by adopting the configuration in which different semiconductor chips 1 share the evaluation value obtainment processing and the state determination processing. At this time, the semiconductor chip 1 that executes the state determination processing may be a semiconductor chip that is not involved in transmission/reception of wireless signals corresponding to the evaluation values to be used (e.g., a non-illustrated semiconductor chip 1c or the like).

Although the present embodiment has been described above, the above-described embodiment is intended to facilitate the understanding of the present invention, and is not intended to limit the interpretation of the present invention. The present invention can be changed or reformed without departing from the purport thereof, and the present invention also encompasses equivalents thereof. For example, the semiconductor chips 1 may be configured to include an interposer and a substrate (not shown).

What is claimed is:

1. An information processing apparatus comprising a first semiconductor chip and a second semiconductor chip that performs wireless communication with the first semiconductor chip, wherein
the first semiconductor chip includes:
a processor that executes information processing; and
a communication circuit configured to receive a wireless signal from the second semiconductor chip, and
the processor functions as a state determination unit configured to determine a state of at least one of the first semiconductor chip and the second semiconductor chip on a basis of a time-series change in a measurement value of the wireless signal received from the second semiconductor chip via the communication circuit.

2. The information processing apparatus according to claim 1, wherein
based on the time-series change in the measurement value, the state determination unit determines which one of a change in a relative position between the first semiconductor chip and the second semiconductor chip, and a failure in the first or second semiconductor chip, has occurred.

3. The information processing apparatus according to claim 2, wherein
based on the time-series change in the measurement value, the state determination unit determines which one of a change in a relative distance between the first semiconductor chip and the second semiconductor chip, and a failure in the first or second semiconductor chip, has occurred.

4. The information processing apparatus according to claim 1, wherein
based on the time-series change in the measurement value, the state determination unit determines which one of a change in a relative angle between the first semiconductor chip and the second semiconductor chip, and a failure in the first or second semiconductor chip, has occurred.

5. The information processing apparatus according to claim 2, wherein
based on the time-series change in the measurement value, the state determination unit determines a state of one of a change in a relative distance between the first semiconductor chip and the second semiconductor chip, a change in a relative angle between the first semiconductor chip and the second semiconductor chip, and a failure in the first or second semiconductor chip.

6. The information processing apparatus according to claim 2, wherein
the first semiconductor chip further includes a memory having a reference information storage area for recording the measurement value or information related to the measurement value as reference information in a case of a reference state in which the wireless signal received from the second semiconductor chip via the communication circuit satisfies a predetermined reference condition, and
the state determination unit determines a change in a relative position between the first semiconductor chip and the second semiconductor chip on a basis of the measurement value of the wireless signal received via the communication circuit and the reference information stored in the reference information storage area.

7. The information processing apparatus according to claim 4, wherein
the first semiconductor chip further includes a memory having a reference information storage area for recording the measurement value or information related to the measurement value as reference information in a case of a reference state in which the wireless signal received from the second semiconductor chip via the communication circuit satisfies a predetermined reference condition, and
the state determination unit determines a change in a relative angle between the first semiconductor chip and the second semiconductor chip on a basis of the measurement value of the wireless signal received via the communication circuit and the reference information stored in the reference information storage area.

8. The information processing apparatus according to claim 6, wherein
the case of the reference state in which the predetermined reference condition is satisfied is a case where a state in which a range of a change in an amplitude of the measurement value of the wireless signal is smaller than a predetermined range has continued for a first predetermined time period.

9. The information processing apparatus according to claim 6, wherein
the state determination unit
determines that a relative distance between the first semiconductor chip and the second semiconductor chip has become longer than the relative distance in the reference state in a case where an amplitude of the measurement value of the wireless signal received via the communication circuit has gradually decreased and become a value smaller than the reference information stored in the reference information storage area, and
determines that a failure has occurred in the first or second semiconductor chip in a case where the amplitude of the measurement value of the wireless signal received via the communication circuit has become a near-zero value in a time period shorter than a second predetermined time period.

10. The information processing apparatus according to claim 7, wherein
the first and second semiconductor chips are horizontally arranged on a substantially same plane, and
the state determination unit
determines that the relative angle between the first semiconductor chip and the second semiconductor chip has changed from a state of the horizontal arrangement on the same plane in a case where an amplitude of the measurement value of the wireless signal received via the communication circuit has gradually increased and become a value larger than the reference information stored in the reference information storage area, and
determines that a failure has occurred in the first or second semiconductor chip in a case where the amplitude of the measurement value of the wireless signal received via the communication circuit has become a near-zero value in a time period shorter than a second predetermined time period.

11. The information processing apparatus according to claim 7, wherein
the first and second semiconductor chips are arranged so that surfaces thereof oppose each other, and
the state determination unit
determines that a relative angle between the first semiconductor chip and the second semiconductor chip has changed from a state of the arrangement in a case where an amplitude of the measurement value of the wireless signal received via the communication circuit has gradually decreased and become a value smaller than the reference information stored in the reference information storage area, and
determines that a failure has occurred in the first or second semiconductor chip in a case where the amplitude of the measurement value of the wireless signal received via the communication circuit has become a near-zero value in a time period shorter than a second predetermined time period.

12. A first semiconductor chip, comprising:
a communication circuit; and
a processer which functions as:
an obtainment unit configured to obtain an evaluation value indicating a quality of a wireless signal received from a second semiconductor chip via the communication circuit; and
a determination unit configured to determine, based on the evaluation value, a state of at least one of the first semiconductor chip and the second semiconductor chip.

13. The first semiconductor chip according to claim 12, wherein
the communication circuit includes a first coil, and performs wireless communication with the second semiconductor chip with use of inductive coupling between the first coil and a second coil in the second semiconductor chip.

14. The first semiconductor chip according to claim 12, wherein
in a case where the evaluation value satisfies a predetermined condition, the determination unit determines that a change in a relative position between the first semiconductor chip and the second semiconductor chip has occurred.

15. The first semiconductor chip according to claim 12, wherein
the evaluation value is based on a voltage value of the wireless signal.

16. The first semiconductor chip according to claim 15, wherein
the wireless signal includes a specific signal part for transmitting a predetermined signal sequence, and
the evaluation value is based on a voltage value of the specific signal part of the wireless signal.

17. The first semiconductor chip according to claim 12, wherein
the evaluation value is based on a number of bit errors in the wireless signal.

18. The first semiconductor chip according to claim 17, wherein
the wireless signal includes a specific signal part for transmitting a predetermined signal sequence, and
the evaluation value is based on a number of bit errors in the specific signal part of the wireless signal.

19. A first semiconductor chip, comprising:
a communication circuit; and
a processer which functions as:
an obtainment unit configured to obtain an evaluation value indicating a quality of a wireless signal transmitted to a second semiconductor chip via the communication circuit; and
a determination unit configured to determine, based on the evaluation value, whether or not a change in a relative position between the first semiconductor chip and the second semiconductor chip has occurred.

20. The first semiconductor chip according to claim 19, wherein
the communication circuit includes a first coil, and performs wireless communication with the second semiconductor chip with use of inductive coupling between the first coil and a second coil in the second semiconductor chip.

21. An information processing apparatus comprising a first semiconductor chip and a second semiconductor chip, wherein
the first semiconductor chip includes:
a first communication circuit; and
a first processor which functions as:
an obtainment unit configured to obtain an evaluation value indicating a quality of a wireless signal received from the second semiconductor chip via the first communication circuit; and
a transmission unit configured to transmit the evaluation value to the second semiconductor chip via the first communication circuit, and
the second semiconductor chip includes:
a second communication circuit; and
a second processor which functions as a determination unit configured to determine a state of at least one of the first semiconductor chip and the second semiconductor chip on a basis of the evaluation value received from the first semiconductor chip via the second communication circuit.

22. A control method for a first semiconductor chip comprising a communication circuit, comprising:
obtaining an evaluation value indicating a quality of a wireless signal received from a second semiconductor chip via the communication circuit; and
determining, based on the evaluation value, a state of at least one of the first semiconductor chip and the second semiconductor chip.
